(19) United States
(12) Patent Application Publication
(10) Pub. No.: US 2026/0262299 A1
(43) Pub. Date: Sep. 3, 2026

(54) SEMICONDUCTOR DEVICE AND METHOD FOR TUNING HOLDING VOLTAGES IN SILICON CONTROLLED RECTIFIER

(71) Applicant: Indian Institute of Science, Bangalore (IN)

(72) Inventors: Mayank Yadav, Bangalore (IN); Mayank Shrivastava, Bangalore (IN)

(21) Appl. No.: 19/331,060

(22) Filed: Sep. 17, 2025

(30) Foreign Application Priority Data
Feb. 28, 2025 (IN) 202541018106

(51) Int. Cl. H10D 89/60; H10D 84/01; H10D 84/60

(52) U.S. Cl. CPC H10D 89/713; H10D 84/0112; H10D 84/611; H10D 89/611

(57) ABSTRACT

The present disclosure relates to semiconductor device (900A) including first P+ implanted and diffused regions (904-1, 908-1) over second N+ implanted and diffused regions (904-2, 908-2), forming p-n junctions. The first P+ implanted and diffused regions (904-1, 908-1) provide an electrical contact to an external environment, and the second P+ implanted and diffused regions (902-2, 906-2) are in direct contact with the deeply diffused first and second regions (910, 912). The first N+ implanted and diffused regions (902-1, 906-1) over the second P+ implanted and diffused regions (902-2, 906-2) form the p-n junction. The first N+ implanted and diffused regions (902-1, 906-1) provide an electrical contact to the external environment, and the second N+ implanted and diffused regions (904-2, 908-2) are in direct contact with the deeply diffused first and second regions (910, 912).

Portions of this patent document may contain material that may be subject to Copyright or Trademark protection. The owner has no objection to the facsimile reproduction by anyone of the patent document or the patent disclosure, as it appears in the Patent and Trademark Office file or records, but otherwise reserves all copyright rights and trademarks whatsoever. All copyrights and trademarks are owned by Indian Institute of Science, Bangalore.

### TECHNICAL FIELD

The present disclosure relates generally to the field of semiconductor devices. In particular, the present disclosure relates to a semiconductor device and a method for tuning holding voltages in a silicon-controlled rectifier for protection of integrated circuits (ICs).

### BACKGROUND

The background information provided hereunder is instructive for understanding the present disclosure but does not necessarily constitute prior art with respect to any of the embodiments of the present disclosure described herein.

Electrostatic discharge (ESD) occurs when two bodies with different electrostatic potentials come into contact, leading to a sudden transfer of charge. This phenomenon can be modeled in different ways, namely: Human Body Model (HBM) represents discharge from human touch, a Charged Device Model (CDM) simulates a charged device abruptly grounding, and a Machine Model (MM) accounts for discharge from large machinery accidentally grounded by a chip. During an ESD event, a significant surge of current flows between the bodies for a few hundred nanoseconds.

Low-voltage integrated circuits (ICs) are particularly vulnerable to high-voltage ESD events if not adequately protected. When an ESD event occurs at an IC's Input/Output (I/O) pins, the sudden surge of current may lead to catastrophic failures such as gate oxide breakdown or meltdown of an active device area. To prevent such damage, an ESD protection device is placed in parallel with the I/O pins. The ESD protection device remains off during normal operation but activates during the ESD event at a voltage lower than the IC's failure threshold. Additionally, the ESD protection device must maintain a holding voltage higher than the IC's operating voltage to prevent latch-up conditions. However, in low-holding voltage Complementary Metal-Oxide-Semiconductor (CMOS) processes, resulting holding voltage (<1.5 V) may lead to latch-up issues during normal IC operation and significantly reduce the ESD protection window. Due to high voltage failure risk in the ICs, the ESD protection devices (e.g., Silicon Controlled Rectifiers (SCRs)) are essential.

As illustrated in FIG. 1, conventional SCRs 100 are widely used for ESD protection due to their favorable trigger voltage, holding voltage, and failure current characteristics. The SCR 100 operates using two bipolar junction transistors (BJTs) (PNP and NPN) in a positive feedback configuration. The introduction of parallel p-n junctions at the base-emitter regions of these BJTs influences both the trigger and holding voltages of the SCR 100.

Several techniques have been proposed to increase the holding voltage. However, these approaches often come with drawbacks, including increased transient turn-on time, higher capacitance (which lowers operating frequency), and additional silicon area requirements due to implants, making them less suitable for on-chip ESD protection. Moreover, ensuring latch-up robustness in the SCRs remains a critical challenge.

Therefore, there is, a need to address at least the above-mentioned drawbacks and any other shortcomings, or at the very least, provide an improved and cost-effective alternative to the existing methods and systems to tune holding voltages in the SCR.

### OBJECTS OF THE PRESENT DISCLOSURE

Some of the objects of the present disclosure which are sought to be achieved by at least one embodiment herein described are enlisted hereunder.

An object of the present disclosure is to provide a method for tuning holding voltages in a Silicon Controlled Rectifier (SCR).

Another object of the present disclosure is to protect integrated circuits (ICs) by tuning holding voltages in the SCR.

Yet another object of the present disclosure is to provide a semiconductor device that achieves a wide range of holding voltage tunability, by introducing high-energy P+/N+ Electrostatic discharge (ESD) implants at TAP regions, anode, and cathode. These implants enable voltage tuning, reduce capacitance, ensure lower Direct Current (DC) leakage, and enhance transient turn-on performance, leading to a reduction in failure current of the device.

Other objects and advantages of the present disclosure will be more apparent from the following description, which is not intended to limit the scope of the present disclosure.

### SUMMARY

This section is provided to introduce certain objects and aspects of the present disclosure in a simplified form that are further described below in the detailed description. This summary is not intended to identify the key features or the scope of the claimed subject matter.

In an aspect, the present disclosure relates to a semiconductor device. The semiconductor device includes a substrate, and a deeply diffused first region and a deeply diffused second region disposed and configured to form a p-n junction side by side in the substrate. The semiconductor device includes first P+ implanted and diffused regions and first N+ implanted and diffused regions that are formed in both the deeply diffused first region and the deeply diffused second region and isolated by a shallow trench isolation (STI). Further, the semiconductor device includes second P+ implanted and diffused regions and second N+ implanted and diffused regions that are formed in both the deeply diffused first region and the deeply diffused second region and isolated by the STI. The first P+ implanted and diffused regions over the second N+ implanted and diffused regions form the p-n junction. The first P+ implanted and diffused regions are configured to provide an electrical contact to an external environment, and the second P+ implanted and diffused regions are in direct contact with the deeply diffused first and second regions. The first N+ implanted and diffused regions over the second P+ implanted and diffused regions form the p-n junction, and the first N+ implanted and diffused regions are configured to provide an electrical contact to the external environment, and the second N+ implanted and diffused regions are in direct contact with the deeply diffused first and second regions.

In an embodiment, the deeply diffused first region may include a core region. The core region may include a core P+ implanted region underneath a core N+ implanted region, forming a core p-n junction. The core P+ implanted region may be in direct contact with the deeply diffused first region, and the core N+ implanted region may establish an electrical contact with the external environment.

In an embodiment, the deeply diffused second region may include a main region. The main region may include a main P+ implanted region underneath a main N+ implanted region, forming a main p-n junction. The main P+ implanted region may be in direct contact with the deeply diffused second region, and the main N+ implanted region may establish an electrical contact with the external environment.

In an embodiment, the deeply diffused first region may include an auxiliary region. The auxiliary region may include an auxiliary N+ implanted region underneath an auxiliary P+ implanted region, forming an auxiliary p-n junction. The auxiliary N+ implanted region may be in direct contact with the deeply diffused first region, and the auxiliary P+ implanted region may be configured to provide an electrical contact to the external environment.

In an embodiment, the deeply diffused second region may include a peripheral region. The peripheral region may include a peripheral N+ implanted region underneath a peripheral P+ implanted region, forming a peripheral p-n junction. The peripheral N+ implanted region may be in direct contact with the deeply diffused second region, and the peripheral P+ implanted region may be configured to provide an electrical contact to the external environment.

In an embodiment, the core P+ implanted region in the deeply diffused first region may be in direct contact with the main P+ implanted region in the deeply diffused second region via the core p-n junction and the auxiliary p-n junction.

In an embodiment, the auxiliary N+ implanted region in the deeply diffused first region may be in direct contact with the peripheral N+ implanted region in the deeply diffused second region via the auxiliary p-n junction and the peripheral p-n junction.

In an embodiment, the deeply diffused first region may be a P-well region and the deeply diffused second region may be a N-well region.

In an embodiment, the core P+ implanted region underneath the core N+ implanted region in the P-well region may form a PTAP, and the peripheral N+ implanted region underneath the peripheral P+ implanted region in the N-well region may form a NTAP.

In an embodiment, the auxiliary P+ implanted region over the auxiliary N+ implanted region in the P-well region may form a cathode. The main N+ implanted region over the main P+ implanted region in the N-well region may form an anode.

In an embodiment, the semiconductor device may include a central N+ implant region that is symmetrically divided into a first region and a second region by at least two STIs. An upper portion of the central N+ implant region may be electrically floated, and a lower portion of the central N+ implant region may form a p-n junction with the first region.

In an embodiment, the central N+ implant region may be in electrical contact with the first and second P+ implanted and diffused regions, and the first and second N+ implanted and diffused regions.

In an embodiment, the semiconductor device may include a central P+ implant region that may be symmetrically divided into a first region and a second region by at least two STIs or gate oxides. An upper portion of the central P+ implant region may be electrically floated, and a lower portion of the central P+ implant region may form a p-n junction with the second region.

In an embodiment, the central P+ implant region may be in electrical contact with the first and second P+ implanted and diffused regions, and the first and second N+ implanted and diffused regions.

In an aspect, the present disclosure relates to a method for tuning holding voltages in a silicon-controlled rectifier. The method includes positioning a deeply diffused first region and a deeply diffused second region and forming p-n junctions side by side in a substrate. The method includes arranging first P+ implanted and diffused regions and the first N+ implanted and diffused regions in the deeply diffused first region and the deeply diffused second region that are isolated by a STI, forming the p-n junctions. Further, the method includes arranging second P+ implanted and diffused regions and second N+ implanted and diffused regions in the deeply diffused first region and the deeply diffused second region isolated by the STI, forming the p-n junctions for tuning holding voltages in a silicon-controlled rectifier.

In an embodiment, the method may include configuring the first P+ implanted and diffused regions to provide an electrical contact to an external environment, and configuring the first N+ implanted and diffused regions to provide the electrical contact to the external environment.

In an embodiment, the method may include configuring the second N+ implanted and diffused regions to be in direct contact with the deeply diffused first and second regions, and configuring the second P+ implanted and diffused regions to be in direct contact with the deeply diffused first and second regions.

### BRIEF DESCRIPTION OF DRAWINGS

The accompanying drawings, which are incorporated herein, and constitute a part of this disclosure, illustrate exemplary embodiments of the disclosed methods and systems which like reference numerals refer to the same parts throughout the different drawings. Components in the drawings are not necessarily to scale, emphasis instead being placed upon clearly illustrating the principles of the present disclosure. Some drawings may indicate the components using block diagrams and may not represent the internal circuitry of each component. It will be appreciated by those skilled in the art that disclosure of such drawings includes the disclosure of electrical components, electronic components, or circuitry commonly used to implement such components.

FIG. 1 illustrates a schematic view of a conventional silicon-controlled rectifier (SCR).

FIG. 2 illustrates a cross-sectional view of a semiconductor device having a high energy N+ ESD implant beneath a NTAP, in accordance with an embodiment of the present disclosure.

FIG. 3 illustrates a graphical representation depicting current and voltage (I-V) characteristics plot comparing reference and N+ ESD implanted beneath NTAP SCR trigger and holding voltage, and process variation of underneath implant, in accordance with an embodiment of the present disclosure.

FIG. 4A illustrates a cross-sectional view of a semiconductor device having a high energy P+ ESD implant beneath PTAP, in accordance with an embodiment of the present disclosure.

FIG. 4B illustrates a graphical representation depicting I-V characteristics plot comparing reference and P+ ESD implanted beneath PTAP SCR trigger and holding voltage comparison, and process variation of underneath implant, in accordance with an embodiment of the present disclosure.

FIG. 5A illustrates a cross-sectional view of a semiconductor device having a high energy N+ ESD implant beneath a cathode, in accordance with an embodiment of the present disclosure.

FIG. 5B illustrates a graphical representation depicting I-V characteristics plot comparing reference and N+ ESD implanted beneath cathode SCR trigger and holding voltage comparison, and process variation of underneath implant, in accordance with an embodiment of the present disclosure.

FIG. 6A illustrates a cross-sectional view of a semiconductor device having a high energy P+ ESD implant beneath an anode, in accordance with an embodiment of the present disclosure.

FIG. 6B illustrates a graphical representation depicting I-V characteristics plot comparing reference and P+ ESD implanted beneath anode SCR trigger and holding voltage comparison, and process variation of underneath implant, in accordance with an embodiment of the present disclosure.

FIG. 7A illustrates a cross-sectional view of a semiconductor device having a high energy P+ ESD implant beneath the anode and PTAP, in accordance with an embodiment of the present disclosure.

FIG. 7B illustrates a graphical representation depicting I-V characteristics plot comparing reference and P+ ESD implanted beneath the anode and PTAP SCR trigger and holding voltage comparison, and process variation of underneath implant, in accordance with an embodiment of the present disclosure.

FIG. 8A illustrates a cross-sectional view of a semiconductor device having a high energy P+ ESD implant beneath the cathode and NTAP, in accordance with an embodiment of the present disclosure.

FIG. 8B illustrates a graphical representation depicting I-V characteristics plot comparing reference and N+ ESD implanted beneath the cathode and NTAP SCR trigger and holding voltage comparison, and process variation of underneath implant, in accordance with an embodiment of the present disclosure.

FIG. 9A illustrates a cross-sectional view of a semiconductor device having a high energy P+ ESD implant beneath the anode/PTAP and N+ ESD implant beneath the cathode/NTAP, in accordance with an embodiment of the present disclosure.

FIG. 9B illustrates a graphical representation depicting I-V characteristics plot comparing reference and P+ ESD implant beneath the anode/PTAP and N+ ESD implant beneath the cathode/NTAP SCR trigger and holding voltage comparison, and process variation of underneath implant, in accordance with an embodiment of the present disclosure.

FIGS. 10A-10C illustrate graphical representations depicting variations of capacitance, Direct Current (DC) leakage, and transient turn-on time of proposed SCR and conventional SCR devices.

FIGS. 11A, 11B, and 11C illustrate schematic views of different semiconductor devices, in accordance with an embodiment of the present disclosure.

FIG. 12 illustrates a flowchart depicting a method for tuning holding voltages in a SCR, in accordance with an embodiment of the present disclosure.

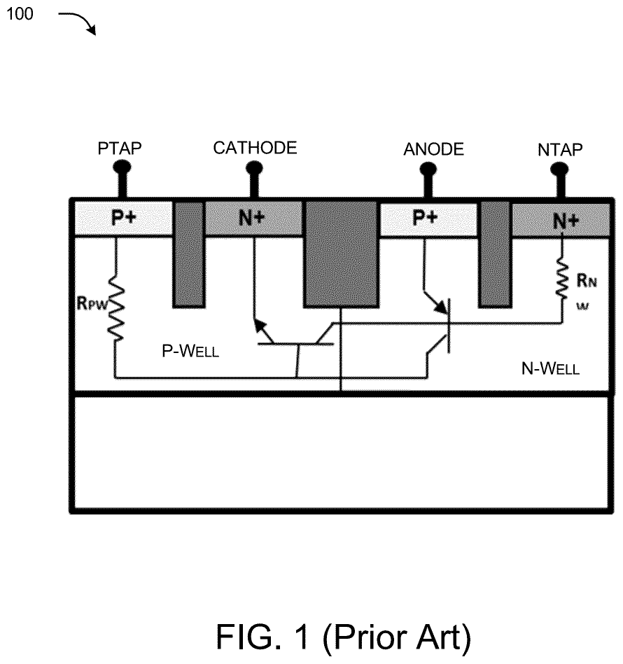

The foregoing shall be more apparent from the following more detailed description of the disclosure.

### DETAILED DESCRIPTION

In the following description, for the purposes of explanation, various specific details are set forth in order to provide a thorough understanding of embodiments of the present disclosure. It will be apparent, however, that embodiments of the present disclosure may be practiced without these specific details. Several features described hereafter can each be used independently of one another or with any combination of other features. An individual feature may not address all of the problems discussed above or might address only some of the problems discussed above. Some of the problems discussed above might not be fully addressed by any of the features described herein.

The ensuing description provides exemplary embodiments only and is not intended to limit the scope, applicability, or configuration of the disclosure. Rather, the ensuing description of the exemplary embodiments will provide those skilled in the art with an enabling description for implementing an exemplary embodiment. It should be understood that various changes may be made in the function and arrangement of elements without departing from the spirit and scope of the disclosure as set forth.

Specific details are given in the following description to provide a thorough understanding of the embodiments. However, it will be understood by one of ordinary skill in the art that the embodiments may be practiced without these specific details. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail to avoid obscuring the embodiments.

Also, it is noted that individual embodiments may be described as a process that is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

The word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used in either the detailed description or the claims, such terms are intended to be inclusive in a manner similar to the term “comprising” as an open transition word without precluding any additional or other elements.

Reference throughout this specification to “one embodiment” or “an embodiment” or “an instance” or “one instance” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The terminology used herein is for the purpose of describing particular embodiments only and is not intended to be limiting of the disclosure. As used herein, the singular forms “a”, “an”, and “the” are intended to include the plural forms as well, unless the context indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

The present disclosure relates generally to the field of semiconductor devices. In particular, the present disclosure relates to a semiconductor device and a method for tuning holding voltages in a silicon-controlled rectifier for protection of integrated circuits (ICs).

The present disclosure discloses a semiconductor device including a substrate, and a deeply diffused first region and a deeply diffused second region disposed and configured to form a p-n junction side by side in the substrate. The semiconductor device includes first P+ implanted and diffused regions and first N+ implanted and diffused regions that are formed in both the deeply diffused first region and the deeply diffused second region and isolated by a shallow trench isolation (STI). Further, the semiconductor device includes second P+ implanted and diffused regions and second N+ implanted and diffused regions that are formed in both the deeply diffused first region and the deeply diffused second region and isolated by the STI. The first P+ implanted and diffused regions over the second N+ implanted and diffused regions form the p-n junction. The first P+ implanted and diffused regions are configured to provide an electrical contact to an external environment, and the second P+ implanted and diffused regions are in direct contact with the deeply diffused first and second regions. The first N+ implanted and diffused regions over the second P+ implanted and diffused regions form the p-n junction, and the first N+ implanted and diffused regions are configured to provide an electrical contact to the external environment, and the second N+ implanted and diffused regions are in direct contact with the deeply diffused first and second regions.

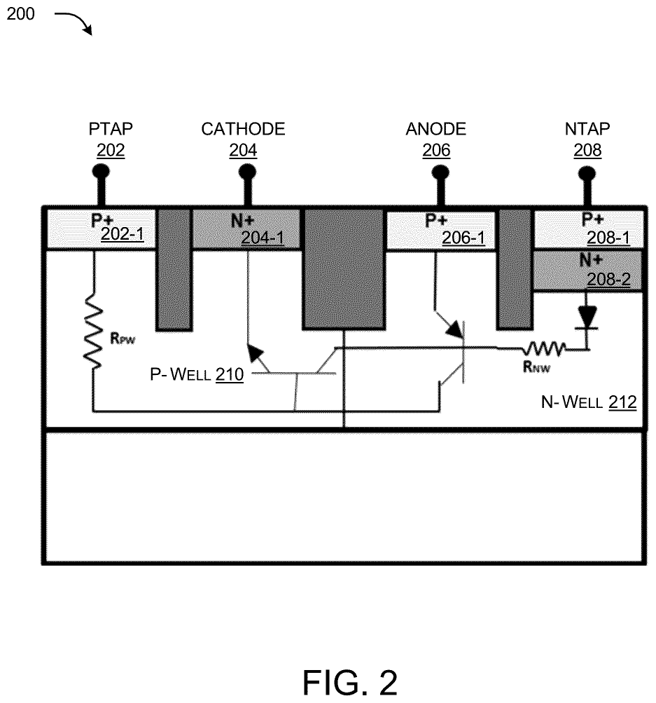

Various embodiments of the present disclosure will be explained in detail with reference to FIGS. 2-10C.

FIG. 2 illustrates a cross-sectional view of a semiconductor device 200 having a high energy N+ ESD implant beneath a NTAP, in accordance with an embodiment of the present disclosure.

In an embodiment, the semiconductor device 200 may include the N+ ESD implant beneath the NTAP and a P+ ESD implant beneath the PTAP. The high-energy implant (i.e., the N+ ESD implant and the P+ ESD implant) may be introduced beneath a normal source/drain implant, forming a p-n junction, thereby influencing behavior of parasitic PNP and NPN Bipolar Junction Transistors (BJTs) present within the SCR 200. The p-n junction may introduce additional bias to the base-emitter junctions of the parasitic BJTs. This biasing effect may alter key electrical characteristics, such as a holding voltage (V_hold) and a triggering voltage (V_trig) of the SCR 200. Therefore, the high-energy implant may modify the holding and triggering voltages of the SCR 200 by influencing the parasitic BJTs. Additionally, due to the implanted layer's series connection, capacitance may be reduced, improving the ESD response time and minimizing circuit interference.

With reference to FIG. 2, the semiconductor device 200 may include a deeply diffused first region (i.e., a P-well region) 210 and a deeply diffused second region (i.e., a N-well region) 212. The P-well region 210 may include a PTAP 202 including a P+ ESD implant 202-1 and a cathode 204 including a N+ ESD implant 204-1. The N-well region 212 may include an anode 206 including a P+ ESD implant 206-1 and a NTAP 208 including a P+ ESD implant 208-1. In an embodiment, a high energy N+ ESD implant 208-2 may be implanted beneath the P+ ESD implant 208-1 of the NTAP 208.

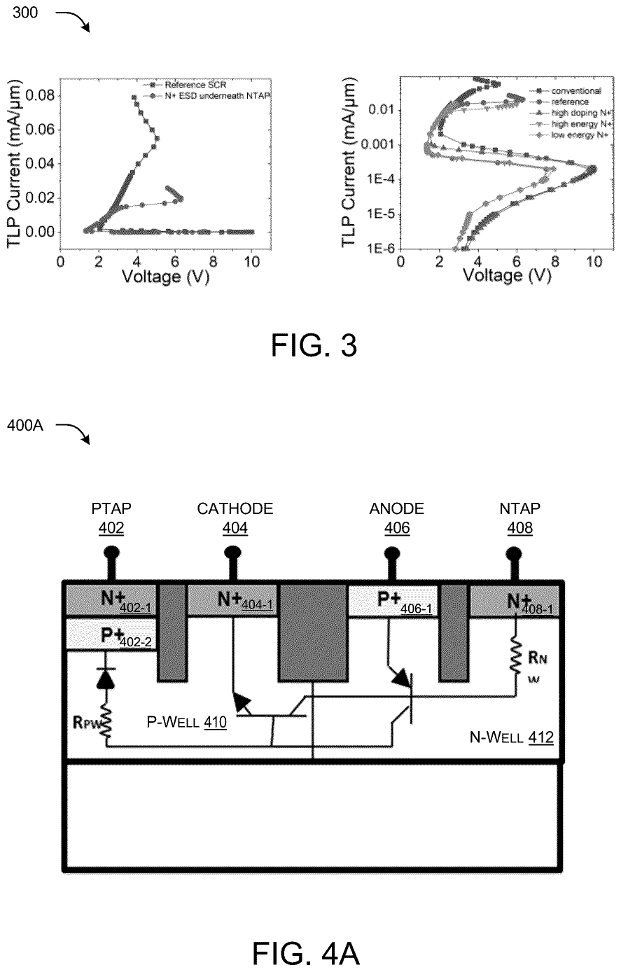

In a low holding voltage Complementary Metal-Oxide-Semiconductor (CMOS) process (as illustrated in FIG. 2), the high energy N+ ESD implant 208-2 placed beneath the NTAP 208 may form a parasitic p-n junction diode within the N-well region 212, introducing a positive potential bias to a base-emitter junction of a parasitic PNP BJT. As a result, the PNP transistor may trigger earlier, leading to a lower holding voltage. Additionally, since the base-emitter junction of the PNP transistor is at a higher voltage for a small injected current, the holding voltage may be decreased further (as illustrated in FIG. 3). FIG. 3 illustrates a graphical representation 300 depicting current and voltage (I-V) characteristics plot comparing reference and N+ ESD implant 208-2 beneath the NTAP SCR trigger and holding voltage, and process variation of underneath N+ ESD implant 208-2. Furthermore, the PNP and NPN transistors may operate in positive feedback, causing the NPN transistor to trigger at a lower voltage, thereby also reducing the triggering voltage.

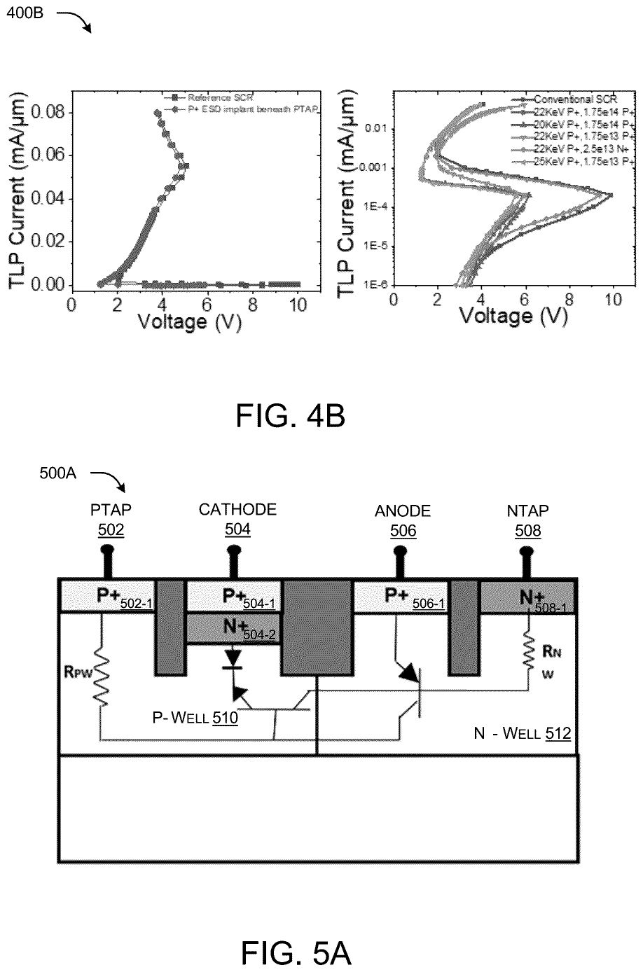

FIG. 4A illustrates a cross-sectional view of a semiconductor device 400A having a high energy P+ ESD implant 402-2 beneath the PTAP 402, in accordance with an embodiment of the present disclosure.

With reference to FIG. 4A, the semiconductor device 400A may include a deeply diffused first region (i.e., a P-well region) 410 and a deeply diffused second region (i.e., a N-well region) 412. The P-well region 410 may include a PTAP 402 including a N+ ESD implant 402-1 and a cathode 404 including a N+ ESD implant 404-1. The N-well region 412 may include an anode 406 including a P+ ESD implant 406-1 and a NTAP 408 including a N+ ESD implant 408-1. In an embodiment, a high energy P+ ESD implant 402-2 may be implanted beneath the N+ ESD implant 402-1 of the PTAP 402.

In a low holding voltage CMOS process (as illustrated in FIG. 4A), the high energy P+ ESD implant 402-2 placed beneath the PTAP 402 may form a parasitic p-n junction diode within the P-well region 410, introducing a positive potential bias to the base-emitter junction of the parasitic NPN BJT. As a result, the NPN transistor may trigger earlier, leading to a lower triggering voltage. Additionally, since the base-emitter junction of the NPN transistor is at a higher voltage for a small injected current, the triggering voltage may be decreased further (as illustrated in FIG. 4B). FIG. 4B illustrates a graphical representation 400B depicting I-V characteristics plot comparing reference and the P+ ESD implant 402-2 beneath the PTAP 402, and process variation of underneath P+ ESD implant 402-2. Furthermore, the PNP and NPN transistors may operate in positive feedback, causing the PNP transistor to trigger at a lower voltage, thereby also reducing the holding voltage.

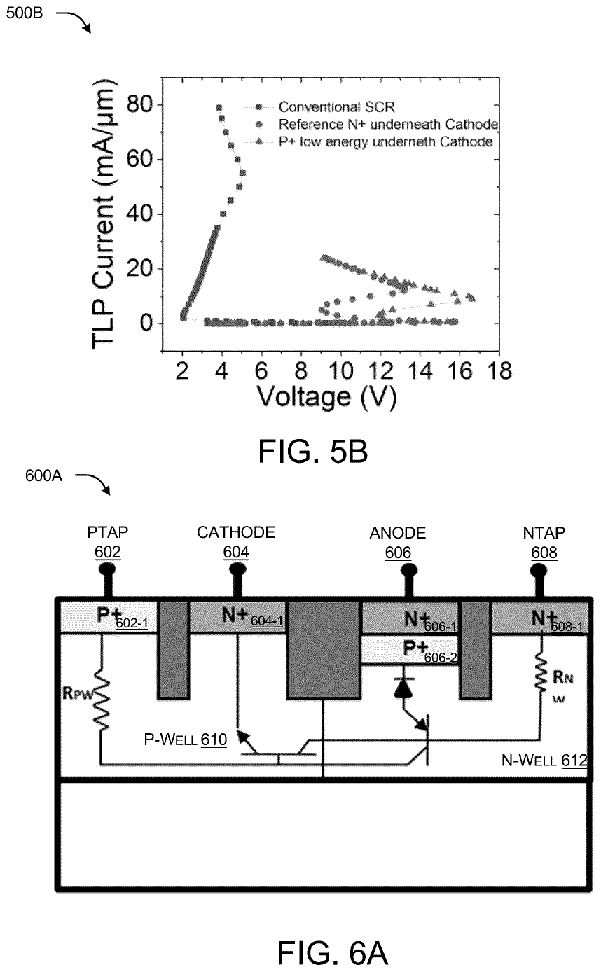

FIG. 5A illustrates a cross-sectional view of a semiconductor device 500A having a high energy N+ ESD implant 504-2 beneath a cathode 504, in accordance with an embodiment of the present disclosure.

With reference to FIG. 5A, the semiconductor device 500A may include a deeply diffused first region (i.e., a P-well region) 510 and a deeply diffused second region (i.e., a N-well region) 512. The P-well region 510 may include a PTAP 502 including a P+ ESD implant 502-1 and the cathode 504 including a P+ ESD implant 504-1. The N-well region 512 may include an anode 506 including a P+ ESD implant 506-1 and a NTAP 508 including a N+ ESD implant 508-1. In an embodiment, a high energy N+ ESD implant 504-2 may be implanted beneath the P+ ESD implant 504-1 of the cathode 504.

The high energy N+ ESD implant 504-2 placed beneath the cathode 504 may form a parasitic p-n junction diode at the base-emitter junction of the NPN transistor (as illustrated in FIG. 5A), introducing a higher potential bias at the base-emitter junction, leading to an increase in trigger voltage. Since the PNP and NPN transistors operate in a positive feedback mechanism, the rise in trigger voltage may consequently result in an increase in holding voltage (as illustrated in FIG. 5B). FIG. 5B illustrates a graphical representation 500B depicting I-V characteristics plot comparing reference and N+ ESD implant 504-2 beneath the cathode 504 (SCR trigger and holding voltage comparison), and process variation of underneath N+ ESD implant 504-2.

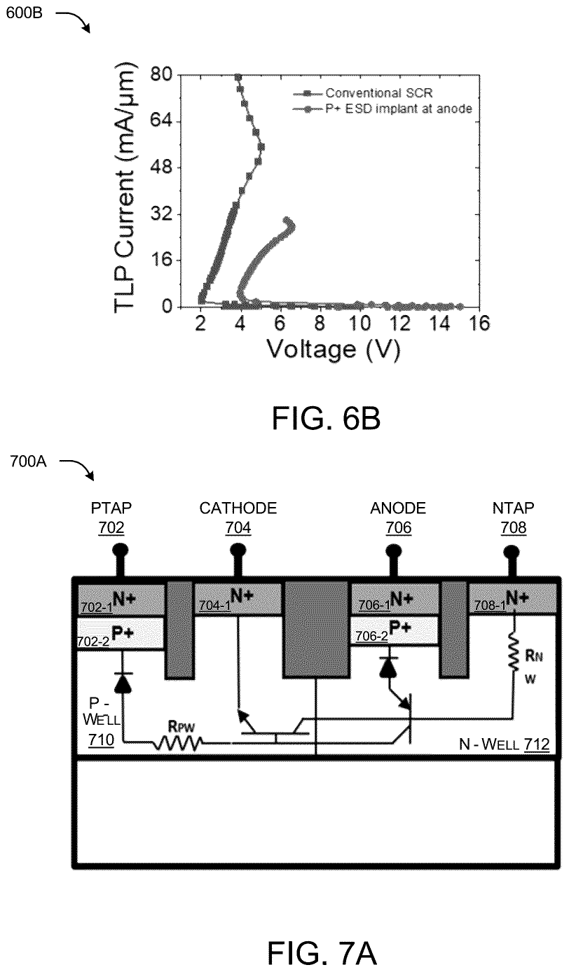

FIG. 6A illustrates a cross-sectional view of a semiconductor device 600A having a high energy P+ ESD implant 606-2 beneath an anode 606, in accordance with an embodiment of the present disclosure.

With reference to FIG. 6A, the semiconductor device 600A may include a deeply diffused first region (i.e., a P-well region) 610 and a deeply diffused second region (i.e., a N-well region) 612. The P-well region 610 may include a PTAP 602 including a P+ ESD implant 602-1 and the cathode 604 including a N+ ESD implant 604-1. The N-well region 612 may include the anode 606 including a N+ ESD implant 606-1 and a NTAP 608 including a N+ ESD implant 608-1. In an embodiment, a high energy P+ ESD implant 606-2 may be implanted beneath the N+ ESD implant 606-1 of the anode 606.

FIG. 6B illustrates a graphical representation 600B depicting the I-V characteristics showing higher holding voltage than conventional SCR with the introduction of the N+-P+ junction (at Itlp=3 mA/um), while the conventional SCR's NPN and PNP had turned-on, whereas the N+-P+ implanted configuration in the anode 606 may weaken a bipolar efficiency, which may increase the holding voltage. However, the trigger voltage may also be increased, forcing a requirement of increased number of injected carriers in the N-well region 612 to forward bias base-emitter voltage V_{BE} (PNP).

Since

$${β}_{PNP} = \frac{{I}_{C}}{{I}_{B}} = \frac{( {I}_{S 1} - {I}_{B} )}{{I}_{B}} , \qquad ( Eq . 1 )$$

lower the value of β_{PNP} may result into a higher holding voltage as depicted in FIG. 6B. As per Eq. (2), VH (Holding Voltage)=V_{EB} (PNP)+V_{BE} (NPN)+V_{RNW}.

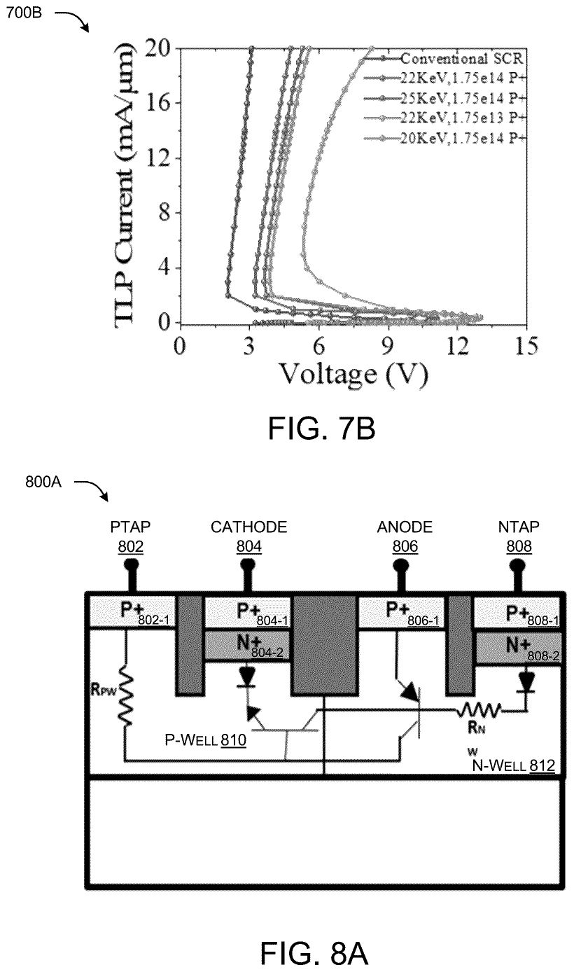

FIG. 7A illustrates a cross-sectional view of a semiconductor device 700A having a high energy P+ ESD implant 702-2, 706-2 beneath the PTAP 702 and the anode 706, in accordance with an embodiment of the present disclosure.

With reference to FIG. 7A, the semiconductor device 700A may include a deeply diffused first region (i.e., a P-well region) 710 and a deeply diffused second region (i.e., a N-well region) 712. The P-well region 710 may include a PTAP 702 including a N+ ESD implant 702-1 and the cathode 704 including a N+ ESD implant 704-1. The N-well region 712 may include the anode 706 including a N+ ESD implant 706-1 and a NTAP 708 including a N+ ESD implant 708-1. In an embodiment, a high energy P+ ESD implant 702-2 may be implanted beneath the N+ ESD implant 702-1 of the PTAP 702, and a high energy P+ ESD implant 706-2 may be implanted beneath the N+ ESD implant 706-1 of the anode 706, thereby ensuring holding voltage tunability by engineering a junction profile (by adjusting the implant energy and dose).

FIG. 7B illustrates a graphical representation 700B depicting I-V characteristics plot comparing reference and P+ ESD implants 702-2 and 706-2 beneath the PTAP and the anode, and process variation of the underneath P+ ESD implants 702-2 and 706-2.

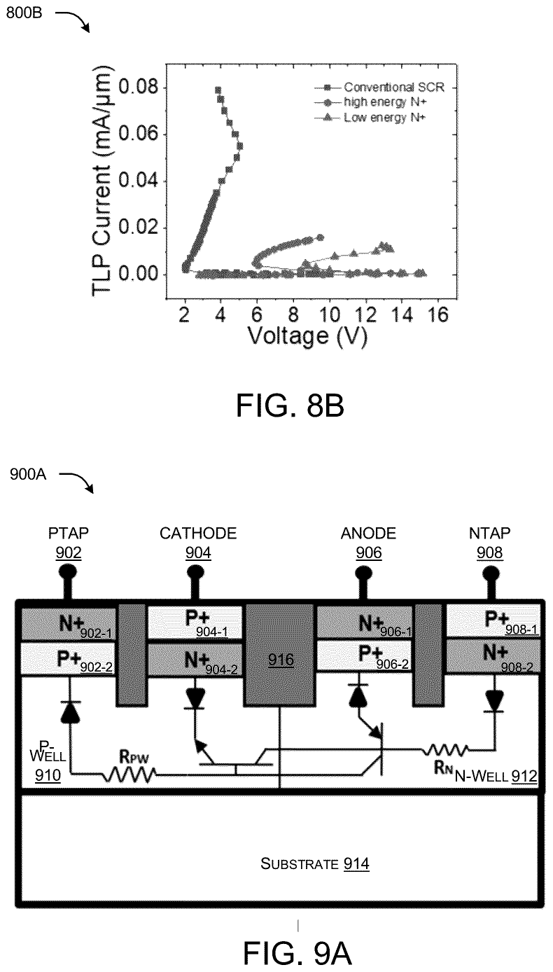

FIG. 8A illustrates a cross-sectional view of a semiconductor device 800A having a high energy P+ ESD implant 804-2 and 808-2 beneath the cathode 804 and the NTAP 808, in accordance with an embodiment of the present disclosure.

With reference to FIG. 8A, the semiconductor device 800A may include a deeply diffused first region (i.e., a P-well region) 810 and a deeply diffused second region (i.e., a N-well region) 812. The P-well region 810 may include a PTAP 802 including a P+ ESD implant 802-1 and the cathode 804 including a P+ ESD implant 804-1. The N-well region 812 may include the anode 806 including a P+ ESD implant 806-1 and a NTAP 808 including a P+ ESD implant 808-1. In an embodiment, a high energy N+ ESD implant 804-2 may be implanted beneath the P+ ESD implant 804-1 of the cathode 804, and a high energy N+ ESD implant 808-2 may be implanted beneath the P+ ESD implant 808-1 of the NTAP 808, enabling trigger and holding voltage tunability by engineering the junction profile (by adjusting the implant energy and dose). Forming junctions may bias the base-emitter in reverse bias which may increase the holding and trigger voltage larger than N-P implant at the NTAP and the anode process variation, as illustrated in FIG. 8B.

FIG. 8B illustrates a graphical representation 800B depicting I-V characteristics plot comparing reference and N+ ESD implants 804-2 and 808-2 beneath the cathode 804 and the NTAP 808 trigger and holding voltage comparison, and process variation of underneath N+ ESD implants 804-2 and 808-2.

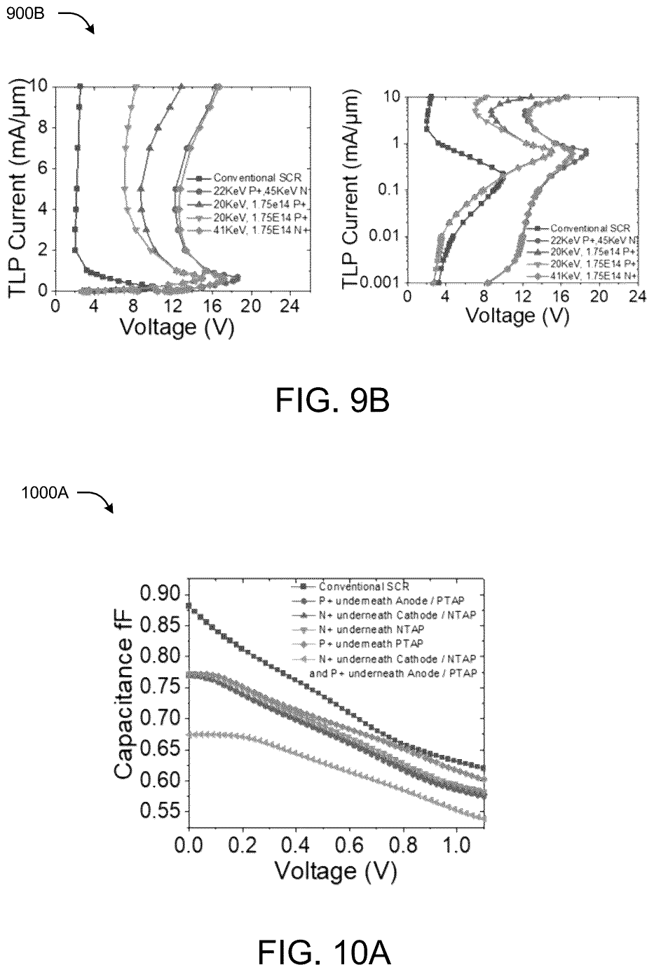

FIG. 9A illustrates a cross-sectional view of a semiconductor device 900A having a high energy P+ ESD implant beneath the anode/PTAP and N+ ESD implant beneath the cathode/NTAP, in accordance with an embodiment of the present disclosure.

With reference to FIG. 9A, the semiconductor device 900A may include a substrate 914, a deeply diffused first region 910, and a deeply diffused second region 912. The deeply diffused first region 910 and the deeply diffused second region 912 may be disposed and configured to form a p-n junction side by side in the substrate 914. The deeply diffused first region 910 may be a P-well region and the deeply diffused second region 912 may be a N-well region.

The semiconductor device 900A may include first P+ implanted and diffused regions 904-1, 908-1 and first N+ implanted and diffused regions 902-1, 906-1 that are formed in both the deeply diffused first region 910 and the deeply diffused second region 912 and isolated by a shallow trench isolation (STI) 916. Further, the semiconductor device 900A may include second P+ implanted and diffused regions 902-2, 906-2 and second N+ implanted and diffused regions 904-2, 908-2 that are formed in both the deeply diffused first region 910 and the deeply diffused second region 912 and isolated by the STI 916. The first P+ implanted and diffused regions 904-1, 908-1 over the second N+ implanted and diffused regions 904-2, 908-2 may form the p-n junction. The first P+ implanted and diffused regions 904-1, 908-1 may be configured to provide an electrical contact to an external environment, and the second P+ implanted and diffused regions 902-2, 906-2 may be in direct contact with the deeply diffused first and second regions 910, 912. The first N+ implanted and diffused regions 902-1, 906-1 over the second P+ implanted and diffused regions 902-2, 906-2 may form the p-n junction. The first N+ implanted and diffused regions 902-1, 906-1 may be configured to provide an electrical contact to the external environment, and the second N+ implanted and diffused regions 904-2, 908-2 may be in direct contact with the deeply diffused first and second regions 910, 912.

In an embodiment, the deeply diffused first region 910 may include a core region (i.e., the PTAP) 902. The core region 902 may include a core P+ implanted region 902-2 underneath a core N+ implanted region 902-1, forming a core p-n junction. The core P+ implanted region 902-2 may be in direct contact with the deeply diffused first region 910, and the core N+ implanted region 902-1 may establish an electrical contact with the external environment.

In an embodiment, the deeply diffused second region 912 may include a main region (i.e., anode) 906. The main region 906 may include a main P+ implanted region 906-2 underneath a main N+ implanted region 906-1, forming a main p-n junction. The main P+ implanted region 906-2 may be in direct contact with the deeply diffused second region 912, and the main N+ implanted region 906-1 may establish an electrical contact with the external environment.

In an embodiment, the deeply diffused first region 910 may include an auxiliary region (i.e., cathode) 904. The auxiliary region 904 may include an auxiliary N+ implanted region 904-2 underneath an auxiliary P+ implanted region 904-1, forming an auxiliary p-n junction. The auxiliary N+ implanted region 904-2 may be in direct contact with the deeply diffused first region 910, and the auxiliary P+ implanted region 904-1 may be configured to provide an electrical contact to the external environment.

In an embodiment, the deeply diffused second region 912 may include a peripheral region (i.e., NTAP) 908. The peripheral region 908 may include a peripheral N+ implanted region 908-2 underneath a peripheral P+ implanted region 908-1, forming a peripheral p-n junction. The peripheral N+ implanted region 908-2 may be in direct contact with the deeply diffused second region 912, and the peripheral P+ implanted region 908-1 may be configured to provide an electrical contact to the external environment.

In an embodiment, the core P+ implanted region 902-2 in the deeply diffused first region 910 may be in direct contact with the main P+ implanted region 906-2 in the deeply diffused second region 912 via the core p-n junction and the auxiliary p-n junction.

In an embodiment, the auxiliary N+ implanted region 904-2 in the deeply diffused first region 910 may be in direct contact with the peripheral N+ implanted region 908-2 in the deeply diffused second region 912 via the auxiliary p-n junction and the peripheral p-n junction.

In an embodiment, the core P+ implanted region 902-2 underneath the core N+ implanted region 902-1 in the P-well region 910 may form the PTAP 902. Further, the peripheral N+ implanted region 908-2 underneath the peripheral P+ implanted region 90-1 in the N-well region 912 may form the NTAP 908.

In an embodiment, the auxiliary P+ implanted region 904-1 over the auxiliary N+ implanted region 904-2 in the P-well region 910 may form the cathode 904. The main N+ implanted region 906-1 over the main P+ implanted region 906-2 in the N-well region 912 may form the anode 906.

By forming the high energy P+ ESD implant or the P+ implanted regions 906-2, 902-2 beneath the anode 906 and/or the PTAP 902, and the N+ ESD implant or the N+ implanted regions 904-2, 908-2 beneath the cathode 904 and/or the NTAP 908 may enhance tunability of the holding and trigger voltage of the device 900A. FIG. 9B illustrates a graphical representation 900B depicting I-V characteristics plot comparing reference and the P+ implanted regions 906-2, 902-2 beneath the anode 906 and/or the PTAP 902, and the N+ ESD implant or the N+ implanted regions 904-2, 908-2 beneath the cathode 904 and/or the NTAP 908, and process variation of underneath the implants.

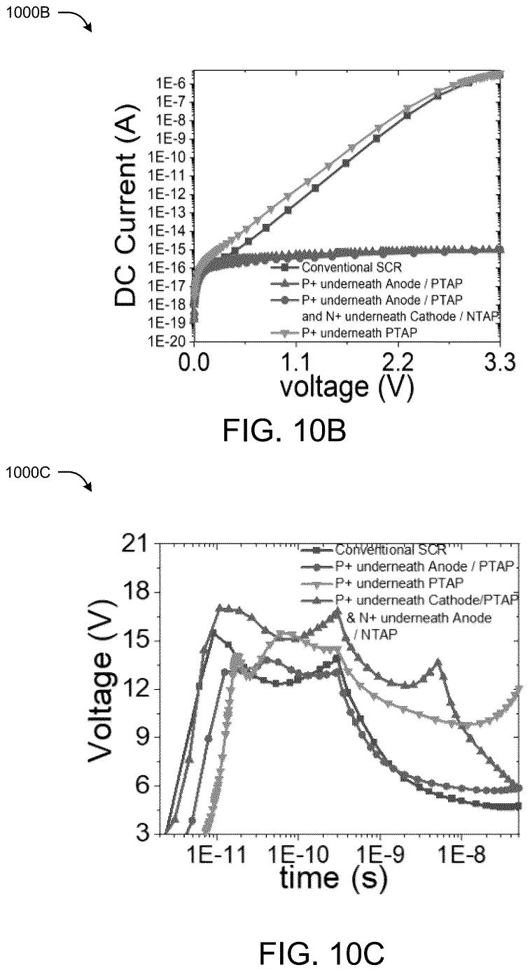

FIGS. 10A-10C illustrate graphical representations 1000A-1000C depicting variations of capacitance, Direct Current (DC) leakage, and transient turn-on time of proposed SCR and conventional SCR devices.

With reference to FIGS. 10A-10C, the graphical representations 1000A-1000C illustrates that holding voltage tunability of the proposed semiconductor device 900A (as illustrated in FIG. 9A) is improved when compared with the conventional SCR, providing immunity to latch-up and widen the ESD protection window. Additionally, the proposed semiconductor device 900A may achieve low capacitance, lower DC leakage, and high-speed transient turn-on time.

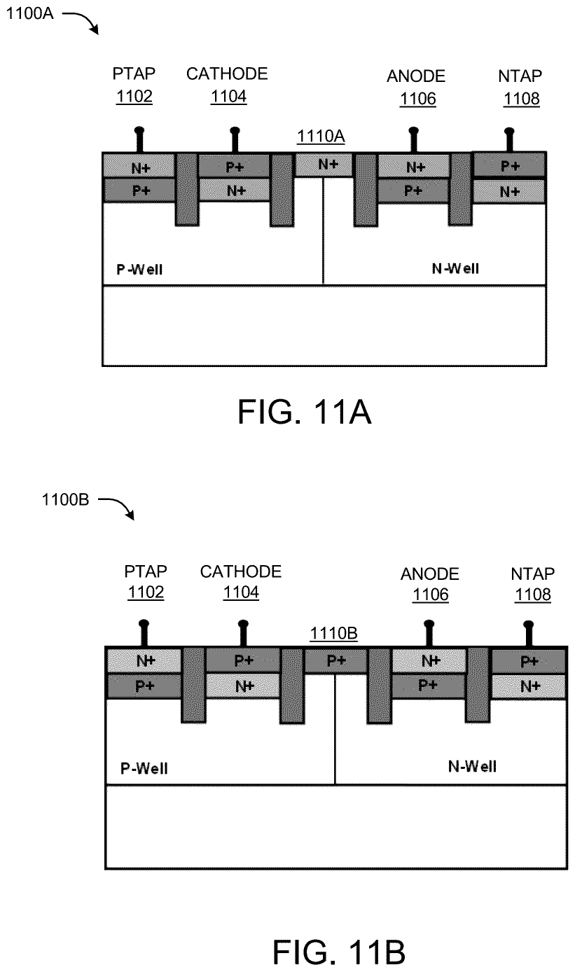

FIGS. 11A, 11B, and 11C illustrate schematic views of different semiconductor devices 1100A, 1100B, and 1100C, in accordance with an embodiment of the present disclosure.

With reference to FIG. 11A, in an embodiment, the semiconductor device 1100A may include a central N+ implant region 1110a that may be symmetrically divided into a first region (P-well region) and a second region (N-well region) by at least two STIs. An upper portion of the central N+ implant region 1110a may be electrically floated, and a lower portion of the central N+ implant region 1110a may form a p-n junction with the first region (P-well region). In an embodiment, the central N+ implant region 1110a may be in electrical contact with the first and second P+ implanted and diffused regions, and the first and second N+ implanted and diffused regions, as illustrated in FIG. 9A.

With reference to FIG. 11B, in an embodiment, the semiconductor device 1100B may include a central P+ implant region 1110b that may be symmetrically divided into a first region (P-well region) and a second region (N-well region) by at least two STIs. An upper portion of the central P+ implant region 1110b may be electrically floated, and a lower portion of the central P+ implant region 1110b may form a p-n junction with the first region (P-well region). In an embodiment, the central P+ implant region 1110b may be in electrical contact with the first and second P+ implanted and diffused regions, and the first and second N+ implanted and diffused regions, as illustrated in FIG. 9A.

With reference to FIG. 11C, in an embodiment, the semiconductor device 1100B may include a central P+ implant region 1110 that may be symmetrically divided into a first region (P-well region) and a second region (N-well region) by at least two STIs or gate oxides 1112. An upper portion of the central P+ implant region 1110 may be electrically floated, and a lower portion of the central P+ implant region 1110 may form a p-n junction with the second region. In an embodiment, the central P+ implant region 1110 may be in electrical contact with the first and second P+ implanted and diffused regions, and the first and second N+ implanted and diffused regions, as illustrated in FIG. 9A.

While the FIGS. 11A-11C describes the semiconductor device 1100A, 1100B, 1100C in a specific configuration (i.e., with the central P+ implant region 1110b, central N+ implant region 1110b, and with gate oxides 1112), it may be appreciated by those skilled in the art that the upper region and the lower region of the semiconductor device 1100A, 1100B, 1100C may be suitably configured based on the requirements as illustrated in FIGS. 2, 4A, 5A, 6A, 7A, and 8A with the central implant regions and the gate oxides.

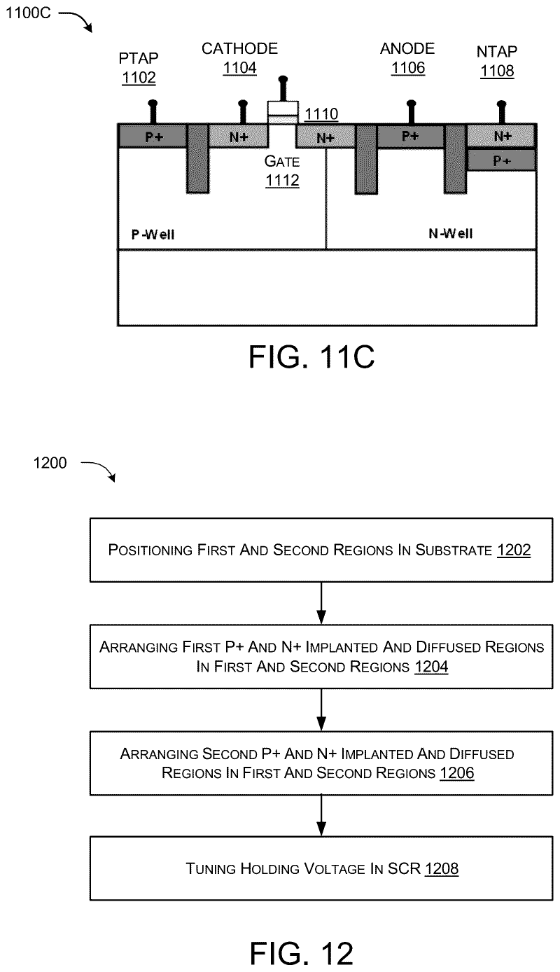

FIG. 12 illustrates a flowchart depicting a method 1200 for tuning holding voltages in a SCR, in accordance with an embodiment of the present disclosure.

With reference to FIG. 12, at 1202, the method 1200 may include positioning a deeply diffused first region and a deeply diffused second region and forming p-n junctions side by side in a substrate.

At 1204, the method 1200 may include arranging first P+ implanted and diffused regions and the first N+ implanted and diffused regions in the deeply diffused first region and the deeply diffused second region that are isolated by a shallow trench isolation (STI), forming the p-n junctions.

At 1206 and 1208, the method 1200 may include arranging second P+ implanted and diffused regions and second N+ implanted and diffused regions in the deeply diffused first region and the deeply diffused second region isolated by the STI, forming the p-n junctions for tuning holding voltages in the SCR.

Further, the method 1200 may include configuring the first P+ implanted and diffused regions to provide an electrical contact to an external environment; and configuring the first N+ implanted and diffused regions to provide the electrical contact to the external environment. In addition, the method 1200 may include configuring the second N+ implanted and diffused regions to be in direct contact with the deeply diffused first and second regions, and configuring the second P+ implanted and diffused regions to be in direct contact with the deeply diffused first and second regions.

Therefore, the method 1200 may improve holding voltage tunability of the SCR, providing immunity to latch-up and widen the ESD protection window. Additionally, the method 1200 may achieve low capacitance, lower DC leakage, and high-speed transient turn-on time.

While considerable emphasis has been placed herein on the preferred embodiments, it will be appreciated that many embodiments can be made and that many changes can be made in the preferred embodiments without departing from the principles of the disclosure. These and other changes in the preferred embodiments of the disclosure will be apparent to those skilled in the art from the disclosure herein, whereby it is to be distinctly understood that the foregoing descriptive matter is to be implemented merely as illustrative of the disclosure and not as a limitation.

### ADVANTAGES OF THE PRESENT DISCLOSURE

The present disclosure described herein above provides certain technical advancements over the existing prior art including, but not limited to:

The present disclosure improves holding voltage tunability of a silicon-controlled rectifier (SCR), providing immunity to latch-up and widen an Electrostatic Discharge (ESD) protection window.

The present disclosure achieves low capacitance, lower Direct Current (DC) leakage, and high-speed transient turn-on time in the SCR.

We claim:

1. A semiconductor device (900A) comprising:
a substrate (914);
a deeply diffused first region (910) and a deeply diffused second region (912) disposed and configured to form a p-n junction side by side in the substrate (914);
first P+ implanted and diffused regions (904-1, 908-1) and first N+ implanted and diffused regions (902-1, 906-1) that are formed in both the deeply diffused first region (910) and the deeply diffused second region (912) and isolated by a shallow trench isolation (STI) (916); and
second P+ implanted and diffused regions (902-2, 906-2) and second N+ implanted and diffused regions (904-2, 908-2) that are formed in both the deeply diffused first region (910) and the deeply diffused second region (912) and isolated by the STI (916),
wherein the first P+ implanted and diffused regions (904-1, 908-1) over the second N+ implanted and diffused regions (904-2, 908-2) form the p-n junction, and wherein the first P+ implanted and diffused regions (904-1, 908-1) are configured to provide an electrical contact to an external environment, and the second P+ implanted and diffused regions (902-2, 906-2) are in direct contact with the deeply diffused first and second regions (910, 912); and
wherein the first N+ implanted and diffused regions (902-1, 906-1) over the second P+ implanted and diffused regions (902-2, 906-2) form the p-n junction, and wherein the first N+ implanted and diffused regions (902-1, 906-1) are configured to provide an electrical contact to the external environment, and the second N+ implanted and diffused regions (904-2, 908-2) are in direct contact with the deeply diffused first and second regions (910, 912).

2. The semiconductor device (900A) as claimed in claim 1, wherein the deeply diffused first region (910) comprises a core region (902), wherein the core region (902) comprises a core P+ implanted region (902-2) underneath a core N+ implanted region (902-1), forming a core p-n junction, and wherein the core P+ implanted region (902-2) is in direct contact with the deeply diffused first region (910), and the core N+ implanted region (902-1) establishes an electrical contact with the external environment.

3. The semiconductor device (900A) as claimed in claim 1, wherein the deeply diffused second region (912) comprises a main region (906), wherein the main region (906) comprises a main P+ implanted region (906-2) underneath a main N+ implanted region (906-1), forming a main p-n junction, and wherein the main P+ implanted region (906-2) is in direct contact with the deeply diffused second region (912), and the main N+ implanted region (906-1) establishes an electrical contact with the external environment.

4. The semiconductor device (900A) as claimed in claim 1, wherein the deeply diffused first region (910) comprises an auxiliary region (904), wherein the auxiliary region (904) comprises an auxiliary N+ implanted region (904-2) underneath an auxiliary P+ implanted region (904-1), forming an auxiliary p-n junction, and wherein the auxiliary N+ implanted region (904-2) is in direct contact with the deeply diffused first region (910), and the auxiliary P+ implanted region (904-1) is configured to provide an electrical contact to the external environment.

5. The semiconductor device (900A) as claimed in claim 1, wherein the deeply diffused second region (912) comprises a peripheral region (908), wherein the peripheral region (908) comprises a peripheral N+ implanted region (908-2) underneath a peripheral P+ implanted region (908-1), forming a peripheral p-n junction, and wherein the peripheral N+ implanted region (908-2) is in direct contact with the deeply diffused second region (912), and the peripheral P+ implanted region (908-1) is configured to provide an electrical contact to the external environment.

6. The semiconductor device (900A) as claimed in claim 1, wherein a core P+ implanted region (902-2) in the deeply diffused first region (910) is in direct contact with a main P+ implanted region (906-2) in the deeply diffused second region (912) via the core p-n junction and the auxiliary p-n junction.

7. The semiconductor device (900A) as claimed in claim 1, wherein an auxiliary N+ implanted region (904-2) in the deeply diffused first region (910) is in direct contact with a peripheral N+ implanted region (908-2) in the deeply diffused second region (912) via the auxiliary p-n junction and the peripheral p-n junction.

8. The semiconductor device (900A) as claimed in claim 1, wherein the deeply diffused first region (910) is a P-well region and the deeply diffused second region (912) is a N-well region.

9. The semiconductor device (900A) as claimed in claim 8, wherein a core P+ implanted region (902-2) underneath a core N+ implanted region (902-1) in the P-well region (910) forms a PTAP (902), and wherein a peripheral N+ implanted region (908-2) underneath a peripheral P+ implanted region (908-1) in the N-well region (912) forms a NTAP (908).

10. The semiconductor device (900A) as claimed in claim 8, wherein an auxiliary P+ implanted region (904-1) over an auxiliary N+ implanted region (904-2) in the P-well region (910) forms a cathode (904), and wherein a main N+ implanted region (906-1) over a main P+ implanted region (906-2) in the N-well region (912) forms an anode (906).

11. The semiconductor device (900A) as claimed in claim 1, comprising a central N+ implant region that is symmetrically divided into a first region and a second region by at least two STIs, wherein an upper portion of the central N+ implant region is electrically floated, and a lower portion of the central N+ implant region forms a p-n junction with the first region.

12. The semiconductor device (900A) as claimed in claim 11, wherein the central N+ implant region is in electrical contact with the first and second P+ implanted and diffused regions, and the first and second N+ implanted and diffused regions.

13. The semiconductor device (900A) as claimed in claim 1, comprising a central P+ implant region that is symmetrically divided into a first region and a second region by at least two STIs or gate oxides, wherein an upper portion of the central P+ implant region is electrically floated, and a lower portion of the central P+ implant region forms a p-n junction with the second region.

14. The semiconductor device (900A) as claimed in claim 13, wherein the central P+ implant region is in electrical contact with the first and second P+ implanted and diffused regions, and the first and second N+ implanted and diffused regions.

15. A method (1200) for tuning holding voltages in a silicon-controlled rectifier, the method (1200) comprising:
positioning (1202) a deeply diffused first region and a deeply diffused second region and forming p-n junctions side by side in a substrate;
arranging (1204) first P+ implanted and diffused regions and first N+ implanted and diffused regions in the deeply diffused first region and the deeply diffused second region that are isolated by a shallow trench isolation (STI), forming the p-n junctions; and
arranging (1206) second P+ implanted and diffused regions and second N+ implanted and diffused regions in the deeply diffused first region and the deeply diffused second region isolated by the STI, forming the p-n junctions for tuning (1208) holding voltages in a silicon-controlled rectifier.

16. The method (1200) as claimed in claim 15, comprising:
configuring the first P+ implanted and diffused regions to provide an electrical contact to an external environment; and
configuring the first N+ implanted and diffused regions to provide the electrical contact to the external environment.

17. The method (1200) as claimed in claim 15, comprising:
configuring the second N+ implanted and diffused regions to be in direct contact with the deeply diffused first and second regions; and
configuring the second P+ implanted and diffused regions to be in direct contact with the deeply diffused first and second regions.
